(19) United States
(12) Patent Application Publication
(10) Pub. No.: US 2025/0345971 A1
(43) Pub. Date: Nov. 13, 2025

(54) SHAPING METHOD, SHAPING APPARATUS, AND ARTICLE MANUFACTURING METHOD

(71) Applicant: CANON KABUSHIKI KAISHA, Tokyo (JP)

(72) Inventor: KAZUKI NAKAGAWA, Tochigi (JP)

(21) Appl. No.: 19/198,482

(22) Filed: May 5, 2025

(30) Foreign Application Priority Data
May 9, 2024 (JP) 2024-076691

(51) Int. Cl. B29C 35/08; B29L 11/00

(52) U.S. Cl. CPC B29C 35/0805; B29C 2035/0827; B29L 2011/00

(57) ABSTRACT

The present invention provides a shaping method of performing a process of shaping a composition on a substrate by using a mold, with respect to each of a plurality of regions on the substrate, wherein the process includes curing the composition on the substrate by light irradiation in a state where the mold and the composition are in contact with each other and separating the mold from the cured composition, the plurality of regions including a first region having an outer edge portion of the substrate, and the light irradiation is performed so as to make an irradiation light amount for the outer edge portion become smaller than that for a portion other than the outer edge portion, in the curing for the first region, and the first region is additionally irradiated with light after the separating for the first region.

### BACKGROUND OF THE INVENTION

### Field of the Invention

The present invention relates to a shaping method, a shaping apparatus, and an article manufacturing method.

### Description of the Related Art

With a growing demand for the miniaturization of semiconductor devices, much attention has been paid to imprint techniques (for example, Japanese Patent Laid-Open No. 2007-509769) in addition to conventional photolithography techniques. An imprint technique is a microfabrication technique of forming the pattern of an imprint material on a substrate by performing the imprint process of shaping an imprint material (composition) on the substrate using a mold. One of the methods of curing an imprint material in imprint process is, for example, a photo-curing method. In imprint process using the photo-curing method, an imprint material on a substrate is cured by light irradiation while a mold and the imprint material are in contact with each other, and the mold is separated from the cured imprint material, thereby forming the pattern of the imprint material on the substrate. Using such an imprint technique can form a fine structure on a several nanometer order on the substrate.

The imprint process is performed for each of a plurality of shot regions on a substrate. Recently, the imprint process is required to be performed for even a shot region including an outer edge portion of a substrate (a so-called partial shot region) in order to improve the yield of product chips obtained from the substrate. Warpage or a stepped portion is sometimes formed on an outer edge portion of a substrate. An imprint material can be supplied in the form of droplets to such an outer edge portion to prevent a mold from directly coming into contact with the substrate. However, the droplets of the imprint material supplied to the outer edge portion of the substrate on which warpage or a stepped portion is formed are not sufficiently in contact with (mold pressing) the mold and hence are not sometimes spread on the substrate and partly kept adhering to the mold after the imprint process. If the imprint material adhering to the mold is cured, the material can be a factor that causes a pattern defect in the imprint process for a subsequent shot region.

### SUMMARY OF THE INVENTION

The present invention provides a technique advantageous in reducing a defect occurring in a composition in the process of shaping the composition on a substrate by using a mold.

According to one aspect of the present invention, there is provided a shaping method of performing a process of shaping a composition on a substrate by using a mold, with respect to each of a plurality of regions on the substrate, wherein the process includes curing the composition on the substrate by light irradiation in a state where the mold and the composition are in contact with each other and separating the mold from the cured composition, the plurality of regions including a first region having an outer edge portion of the substrate, and the light irradiation is performed so as to make an irradiation light amount per unit area for the outer edge portion become smaller than that for a portion other than the outer edge portion, in the curing for the first region, and the first region is additionally irradiated with light after the separating for the first region.

Further features of the present invention will become apparent from the following description of exemplary embodiments with reference to the attached drawings.

### BRIEF DESCRIPTION OF THE DRAWINGS

FIG. 1 is a schematic view showing an example of the arrangement of an imprint apparatus according to the first embodiment;

FIG. 2 is a view showing an example of the layout of a plurality of shot regions on a substrate;

FIG. 3 is a flowchart showing an imprint process according to the first embodiment;

FIGS. 4A to 4G are views for explaining a conventional imprint process;

FIGS. 5A to 5G are views for explaining a conventional imprint process;

FIGS. 6A to 6G are views for explaining an imprint process according to the first embodiment;

FIGS. 7A to 7G are views for explaining an imprint process according to the first embodiment;

FIG. 8 is a view showing an example of performing additional light irradiation by using a third light irradiator;

FIG. 9 is a view showing light irradiation in a curing step in the second embodiment;

FIG. 10 is a view for explaining additional light irradiation for a partial shot region according to the third embodiment; and

FIGS. 11A to 11F are views for explaining an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate.

Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate are defined as the X-Y plane, unless otherwise specified. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are OX, 6Y, and 6Z, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the 6X-axis, the 6Y-axis, and the 6Z-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and an attitude is information that can be specified by values on the 6X-, 6Y-, and 6Z-axes.

A shaping apparatus according to the present invention is an apparatus that performs a shaping process of shaping a composition on a substrate by pressing a mold against the composition. Examples of the shaping apparatus are an imprint apparatus and a planarization apparatus. The imprint apparatus is an apparatus that brings a mold having a concave-convex pattern into contact with a composition (imprint material) on a substrate to form (transfer) the pattern on the composition. The shaping process performed by the imprint apparatus is sometimes called an imprint process. The planarization apparatus is an apparatus that brings a mold having a flat surface into contact with a composition on a substrate to planarize a surface of the composition. The shaping process performed by the planarization apparatus is sometimes called a planarization process. Hereinafter, an imprint apparatus will be exemplified as the shaping apparatus, but arrangement/process of the imprint apparatus can also be applied to the planarization apparatus.

### First Embodiment

The first embodiment according to the present invention will be described. An imprint apparatus is a lithography apparatus that shapes an imprint material (composition) on a substrate by using a mold and can be used for a lithography process that is a manufacturing process for devices such as semiconductor devise and magnetic storage media. The imprint apparatus forms the pattern of a cured material, to which the pattern of a mold is transferred, on a substrate by bringing an uncured imprint material supplied onto the substrate into contact with the mold and giving the imprint material with energy for curing. This process is called an imprint process and performed for each of a plurality of shot regions (imprint regions) on a substrate. The present embodiment describes an example using a photo-curing method of curing an imprint material on a substrate by irradiating the material with light (ultraviolet light).

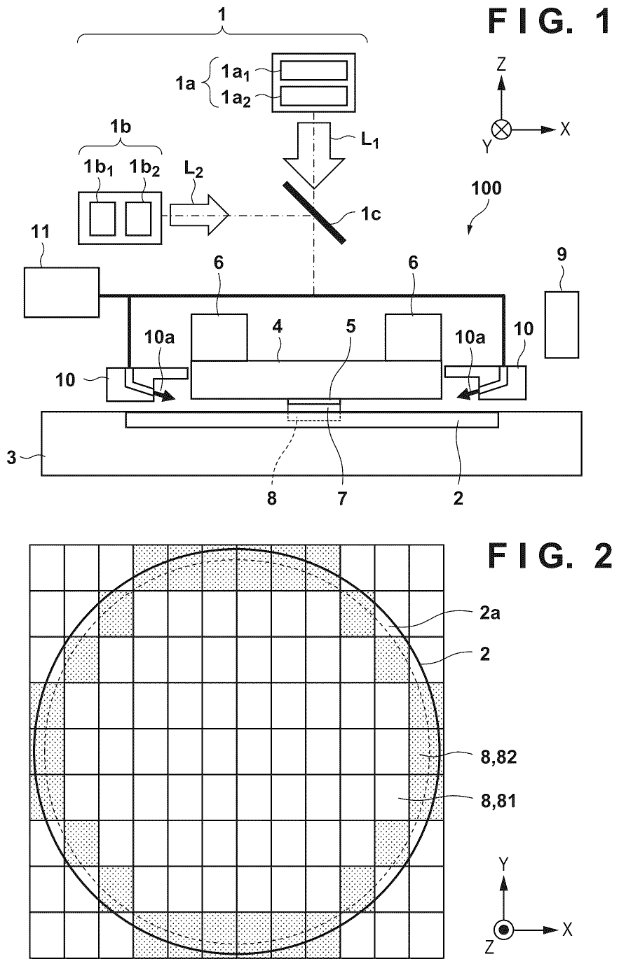

FIG. 1 is a schematic view showing an example of the arrangement of an imprint apparatus 100 according to the present embodiment. The imprint apparatus 100 according to the present embodiment includes a light irradiator 1, a substrate stage 3, a mold holder 6, a liquid supplier 9, a gas supplier 10, and a controller 11. The controller 11 is implemented by a computer (information processor) including a processor such as a Central Processing Unit (CPU) and a storage unit such as a memory. The controller 11 is connected to each unit of the imprint apparatus 100 via a line and controls each unit of the imprint apparatus 100 (controls the imprint process).

The light irradiator 1 is a mechanism that irradiates a substrate 2 (more specifically, an imprint material 7 on the substrate 2) with light. The light irradiator 1 according to the present embodiment can include a first light irradiator 1a used to entirely irradiate one shot region with light L₁ and a second light irradiator 1b used to locally irradiate one shot region with light L₂. The light L₁ and the light L₂ each are light that causes a polymerization reaction on the imprint material 7 and are, for example, ultraviolet light. The light irradiator 1 also includes a half mirror 1c for guiding the light L₁ from the first light irradiator 1a and the light L₂ from the second light irradiator 1b to a mold 4.

The first light irradiator 1a cures the imprint material 7 by irradiating the substrate 2 (the imprint material 7) with light L₁ in a state where the mold 4 and the imprint material 7 on the substrate 2 (a shot region) are in contact with each other, in the imprint process. The first light irradiator 1a can include a light source lai that emits the light L₁ and an optical element 1a₂ for adjusting the light L₁ emitted from the light source lai to light suitable for the imprint process. As the light source lai, a lamp, laser diode, light emitting diode (LED), or the like can be used.

Likewise, the second light irradiator 1b cures the imprint material 7 by irradiating the substrate 2 (the imprint material 7) with the light L₂ in a state where the mold 4 and the imprint material 7 on the substrate 2 (a shot region) are in contact with each other, in the imprint process. The second light irradiator 1b can include a light source 1b₁ that emits the light L₂ and an optical element 1b₂ for adjusting the light L₂ emitted from the light source 1b₁ to light suitable for the imprint process. As the light source lbi, a lamp, laser diode, light emitting diode (LED), or the like can be used.

In this case, the second light irradiator 1b according to the present embodiment can include, as the optical element 1b₂, a light adjuster for adjusting (changing) the irradiation region and/or intensity of the light L₂ onto the substrate 2 in accordance with the shape of a shot region for which the imprint process is performed. In the following description, the optical element 1b₂ of the second light irradiator 1b is sometimes written as the “optical adjuster 1b₂”. The optical adjuster 1b₂ can include a spatial light modulator that spatially modulates the amplitude, phase, and/or polarization of the light L₂ emitted from the light source lbi. As the spatial light modulator, for example, a digital micromirror device (to be sometimes referred to as a DMD hereinafter) can be used. The DMD includes a plurality of mirror elements arranged on a light reflecting surface and can change the irradiation amount distribution of light by individually adjusting (driving) the planar direction of each mirror element under the control of the controller 11. The optical adjuster 1b₂ can freely adjust (set) the irradiation region or intensity of the light L₂ on the substrate 2 by using a spatial light modulator such as a DMD. Note that the spatial light modulator of the optical adjuster 1b₂ is not limited to a DMD, and a liquid crystal display (LCD) device, Liquid Cystal On Silicon (LCOS) device, or the like may be used.

The mold holder 6 is a mechanism that moves the mold 4 in the Z direction while holding the mold 4. More specifically, the mold holder 6 can include a mold chuck that holds the mold 4 and a mold drive mechanism that drives the mold 4 (mold chuck). For example, the mold holder 6 can hold the mold 4 by attracting a peripheral region of the mold 4 with a vacuum suction force or electrostatic force.

The mold holder 6 can drive the mold 4 in each axial direction so as to perform a pressing operation (mold-pressing operation) with respect to the mold 4 and the imprint material 7 on the substrate 2 and a separating operation (mold-separating operation) of separating the mold 4 from the cured imprint material 7 on the substrate 2. The mold holder 6 may be constituted by a plurality of drive systems such as a coarse drive system and a fine drive system to meet the requirement for accurate positioning of the mold 4. In addition, the mold holder 6 may have an arrangement including a position adjustment function for adjusting the position of the substrate 2 not only in the Z direction but also in the X direction, the Y direction, and rotating directions about the respective axes (6X, 6Y, and 6Z directions) or a tilt function for correcting the tilt of the mold 4. Note that a mold-pressing operation and a mold-separating operation in the imprint process may be implemented by driving the mold 4 in the Z direction using the mold holder 6 or by driving the substrate 2 in the Z direction using the substrate stage 3 (to be described later). Alternatively, a mold-pressing operation and a mold-separating operation may be implemented by relatively driving the mold 4 and the substrate 2 in the Z direction using both the mold holder 6 and the substrate stage 3.

The mold 4 held by the mold holder 6 generally has a rectangular outer peripheral shape and is manufactured by a material that can transmit light (ultraviolet light), such as silica glass. A partial region of the surface of the mold 4 which faces the substrate 2 is provided with a mesa portion 5 formed into a mesa shape having a level difference of about several tens of nm. The surface of the mesa portion 5 on the substrate 2 side functions as a shaping surface (contact surface) which comes into contact with the imprint material 7 on the substrate 2 to shape the imprint material 7. The shaping surface of the mold 4 used in the imprint apparatus 100 is formed as a pattern surface on which a concave-convex pattern to be transferred to the imprint material 7 on the substrate 2, such as a circuit pattern, is formed. In the following description, the mesa portion 5 on which a concave-convex pattern is formed will sometimes be referred to as the “pattern portion 5”. Note that the shaping surface of the mold 4 used in a planarization apparatus is formed as a planarization surface on which no concave-convex pattern is formed.

The substrate stage 3 has a mechanism that moves the substrate 2 in the X and Y directions while holding the substrate 2. More specifically, the substrate stage 3 includes a substrate chuck that holds the substrate 2 and a substrate drive mechanism that drives the substrate 2 (substrate chuck) in each axial direction. The substrate stage 3 can be used to align the mold 4 (the pattern portion 5) with the substrate 2 (a shot region 8) when pressing the mold 4 against the imprint material 7 on the substrate 2 (the shot region 8). The substrate stage 3 may be constituted by a plurality of drive systems such as a coarse drive system and a fine drive system with respect to each of the X and Y directions. The substrate stage 3 may be an arrangement including a position adjusting function for adjusting the position of the substrate 2 in not only the X and Y directions but also in the Z direction and the rotating directions about the respective axes (the OX, 6Y, and 6Z directions) or a tilt function for correcting the tilt of the substrate 2.

As a material for the substrate 2, for example, glass, ceramic, metal, semiconductor, resin, or the like is used. The surface of the substrate 2 may be provided with a member made of a material different from the substrate 2 as needed. For example, the substrate 2 can be a silicon wafer, compound semiconductor wafer, or silica glass. In the present embodiment, the substrate 2 is, for example, a single-crystal silicon substrate or Silicon on Insulator (SOI) substrate. The imprint material 7 on which a pattern is formed by the mold 4 (the pattern portion 5) is supplied (coated) on the processing surface of the substrate 2.

The liquid supplier 9 supplies the imprint material 7 in the form of droplets onto the substrate 2. The liquid supplier 9 may be understood as a liquid discharge head that discharges (sprays) the imprint material 7 in the form of droplets toward the substrate 2. For example, the liquid supplier 9 discharges the imprint material 7 in the form of droplets while the substrate stage 3 moves the substrate 2 relatively to the liquid supplier 9 in the X and Y directions below the liquid supplier 9. This makes it possible to supply the imprint material 7 in the form of droplets onto the substrate 2 (the shot region 8).

As the imprint material 7 supplied onto the substrate 2, a curable composition (to be sometimes referred to as a resin in an uncured state) that is cured upon reception of curing energy. A curable composition is a composition cured by light irradiation or heating. Among these compositions, the curable composition that is cured by light irradiation may contain at least a polymerizable compound and a photopolymerization initiator and may further contain a non-polymerizable compound or solvent as needed. A non-polymerizable compound is at least one type of material selected from the group consisting of a sensitizer, a hydrogen donor, an internal mold release agent, a surfactant, an antioxidant, a polymer component, and the like. The viscosity (at 25° C.) of a viscoelastic material is, for example, 1 mPa-s or more and 100 mPa-s or less. In addition, the imprint material 7 used in the present embodiment has a property (characteristic) of being inhibited by oxygen from being cured.

The gas supplier 10 supplies a gas 10a to the space between the mold 4 and the substrate 2 so as to replace the space with the gas 10a. In the imprint apparatus 100, when the mold 4 comes into contact with the imprint material 7 on the substrate 2 in an air atmosphere, air between the mold 4 and the imprint material 7 can mix (remain) as air bubbles in the imprint material 7. In this case, a portion where air bubbles are generated is not filled with the imprint material 7. If the imprint material 7 is cured in this state, a defect can occur in the pattern of the imprint material 7 formed on the substrate 2. Such a defect is sometimes called a pattern defect or unfilled defect. For this reason, in the imprint apparatus 100 according to the present embodiment, the gas supplier 10 supplies the gas 10a to between the mold 4 and the substrate 2 before the mold 4 is brought into contact with the imprint material 7 on the substrate 2 in the imprint process. The gas 10a is a gas having a lower oxygen concentration than air and can be, for example, a permeate gas that easily permeates through the mold 4 or the imprint material 7 at the time of a mold-pressing operation. As a permeate gas, a rare gas such as helium (He) can be used. In this case, the gas supplier 10 can be arranged around the mold 4 so as to surround the mold 4 held by the mold holder 6. The controller 11 controls the supply amount of the gas 10a supplied between the mold 4 and the substrate 2 by the gas supplier 10.

### [Imprint Process]

As shown in FIG. 2, the imprint apparatus 100 having the above arrangement sequentially executes the imprint process for each of the plurality of shot regions 8 on the substrate 2. In the imprint process, after the mold 4 and the substrate 2 are positioned in a predetermined positional relationship, the mold holder 6 moves the mold 4 in the −Z direction to press (make contact) the pattern portion 5 of the mold 4 against the imprint material 7 on the substrate 2 (the shot region 8). After the imprint material 7 is cured in a state where the pattern portion 5 of the mold 4 and the imprint material 7 on the substrate 2 are in contact with each other, the mold 4 is separated from the cured imprint material 7 on the substrate 2. This makes it possible to form, on the substrate 2, the pattern formed of the cured material of the imprint material 7.

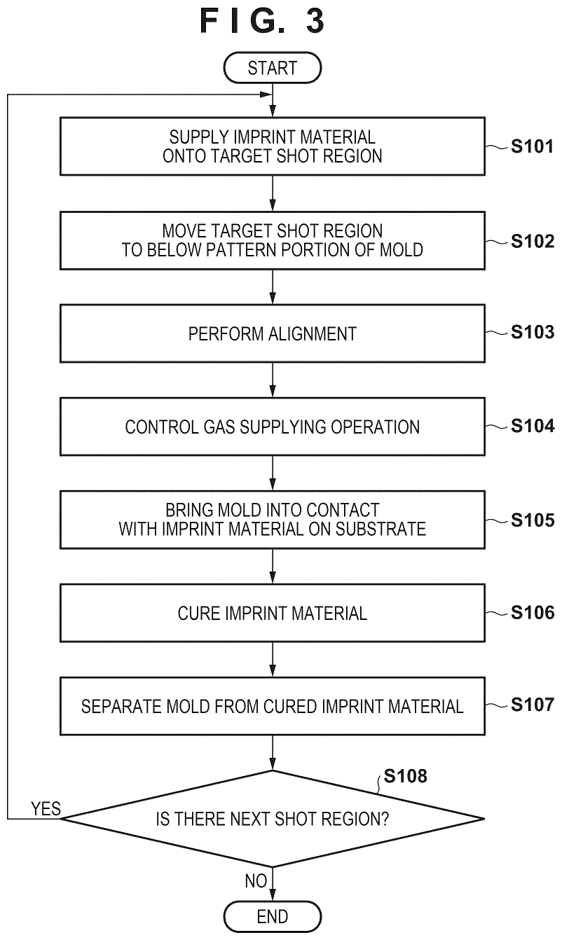

The imprint process according to the present embodiment will be described next. FIG. 3 is a flowchart showing the imprint process according to the present embodiment. The flowchart of FIG. 3 can be executed by the controller 11.

In step S101, the controller 11 supplies the imprint material 7 in the form of droplets onto the shot region 8 (to be sometimes referred to as the target shot region 8 hereinafter), of the plurality of shot regions 8 on the substrate 2, for which the imprint process is to be performed. For example, the controller 11 causes the liquid supplier 9 to discharge the imprint material 7 in the form of droplets while causing the substrate stage 3 to move the substrate 2 in the X and Y directions below the liquid supplier 9. This makes it possible to supply the imprint material 7 in the form of droplets onto the target shot region 8 on the substrate 2.

In step S102, the controller 11 causes the substrate stage 3 to move the substrate 2 so as to place the target shot region 8 of the substrate 2 below the pattern portion 5 of the mold 4. In step S103, the controller 11 aligns the pattern portion 5 of the mold 4 with the target shot region 8 of the substrate 2 by causing the substrate stage 3 to adjust the position of the substrate 2 in the X and Y directions. This alignment can be performed based on the result of measuring the relative position between an alignment mark on the pattern portion 5 and an alignment mark on the target shot region 8 by using an alignment measurement unit (not shown).

In step S104, the controller 11 controls the gas supplying operation of supplying the gas 10a to between the mold 4 and the substrate 2 by using the gas supplier 10. The gas 10a is a gas having a lower oxygen concentration than air. For example, helium can be used as the gas 10a. In the present embodiment, the gas supplying operation in step S104 is performed after step S102. However, limitation is not made thereto. In the imprint apparatus 100, since the interval between the mold 4 and the substrate 2 is very small, it is sometimes difficult to supply the gas 10a to between the mold 4 and the substrate 2 by using the gas supplier 10 while the substrate 2 is placed below the mold 4. For this reason, the gas supplying operation in step S104 may be performed before step S102 of moving the substrate 2 to below the mold 4 or may be performed concurrently with step S102. For example, a gas supplying operation may be performed by causing the gas supplier 10 to supply the gas 10a to below the mold 4 before the substrate 2 is placed below the mold 4 and then moving the substrate 2 to below the mold 4 while the mold 4 is filled with the gas 10a.

In step S105, the controller 11 brings the mold 4 into contact with the imprint material 7 on the substrate 2 by causing the mold holder 6 to move the mold 4 in the −Z direction (contact step/mold-pressing operation). In step S106, the controller 11 causes the light irradiator 1 to cure the imprint material 7 by light irradiation in a state where the mold 4 and the imprint material 7 on the substrate 2 are in contact with each other (curing step). In step S107, the controller 11 separates the mold 4 from the cured imprint material 7 on the substrate 2 by causing the mold holder 6 to move the mold 4 in the +Z direction (mold-separating step/mold-separating operation).

In step S108, the controller 11 determines whether there is the shot region 8 for which the imprint process has not been performed, that is, the shot region for which the imprint process should be performed next (to be sometimes referred to as a next shot region hereinafter) on the substrate 2. If there is a next shot region, the process advances to step S101, in which the controller 11 performs the imprint process for the next shot region as a target shot region. If there is no next shot region, the process is terminated.

As shown in FIG. 2, the plurality of shot regions 8 on the substrate 2 can be roughly classified into full shot regions 81 and partial shot regions 82. The full shot region 81 is the shot region 8 that is placed in the central area of the substrate 2 and does not have an outer edge portion 2a of the substrate 2. The overall pattern provided on the pattern portion 5 of the mold 4 is transferred to the full shot regions 81. The partial shot region 82 is the shot region 8 (the first region) that is placed in a peripheral area of the substrate 2 and has the outer edge portion 2a of the substrate 2. Only part of the pattern provided on the pattern portion 5 of the mold 4 is transferred to the partial shot regions 82. Note that the full shot region 81 is sometimes called a complete shot region or central shot region. The partial shot region 82 is sometimes called a deficient shot region or peripheral shot region.

Recently, in order to improve the yield of product chips obtained from the substrate 2, the imprint process is required to be performed even for the partial shot region 82 having the outer edge portion 2a of the substrate 2. In the imprint process for the partial shot region 82, in order to prevent the mold 4 and the substrate 2 from coming into direct contact with each other, droplets of the imprint material 7 can also be supplied onto the outer edge portion 2a of the substrate 2. However, warpage (deflection) may occur in the outer edge portion 2a of the substrate 2 due to the shape or suction pressure of the substrate stage 3 (substrate chuck) or may have a stepped portion upon undergoing preprocessing (for example, patterning processing for the formation of an underlying pattern). In addition, an outer edge portion of the substrate 2 has sometimes undergone a chamfering process (beveling process). That is, the outer edge portion 2a of the substrate 2 can be formed as a portion having a surface lower in height than the portion other than the outer edge portion 2a. The droplets of the imprint material 7 which are supplied to the outer edge portion 2a described above are insufficiently in contact (mold-pressed) with the mold 4 and hence do not spread on the substrate 2. Consequently, after the imprint process, some of the droplets are sometimes kept adhering to the mold 4. The cured imprint material 7 adhering to the mold 4 can be a factor that causes a pattern defect in the imprint process for a succeeding shot region.

In the imprint apparatus 100 according to the present embodiment, the light irradiator 1 irradiates the outer edge portion 2a with an irradiation light amount per unit area which is smaller than that on the portion other than the outer edge portion 2a in the imprint process (curing step) for the partial shot region 82. For example, the controller 11 controls light irradiation by the light irradiator 1 so as to irradiate the portion other than the outer edge portion 2a with light while not irradiating the outer edge portion 2a with light in the imprint process (curing step) for the partial shot region 82.

This makes it possible to avoid some of droplets of the imprint material 7 supplied to the outer edge portion 2a of the substrate 2 from adhering in a cured state to the pattern portion 5 of the mold 4 in the imprint process for the partial shot region 82. That is, even if the imprint material 7 adheres to the pattern portion 5 of the mold 4 due to the imprint process for the partial shot region 82, it is possible to make the imprint material 7 remain in an uncured state on the pattern portion 5 of the mold 4. The imprint material 7 remaining in the uncured state on the pattern portion 5 of the mold 4 is integrated (mixed, merged, or fused) with the imprint material 7 on the shot region 8 for which the imprint process is performed next. This makes it possible to remove the imprint material 7 remaining on the pattern portion 5 of the mold 4 and reduce the occurrence of pattern defects in the imprint process for the succeeding shot region 8.

The imprint process according to the present embodiment will be described in comparison with the conventional imprint process. Note that the imprint material 7 remaining and adhering to the pattern portion 5 of the mold 4 is sometimes written as a “residual imprint material 7′” hereinafter.

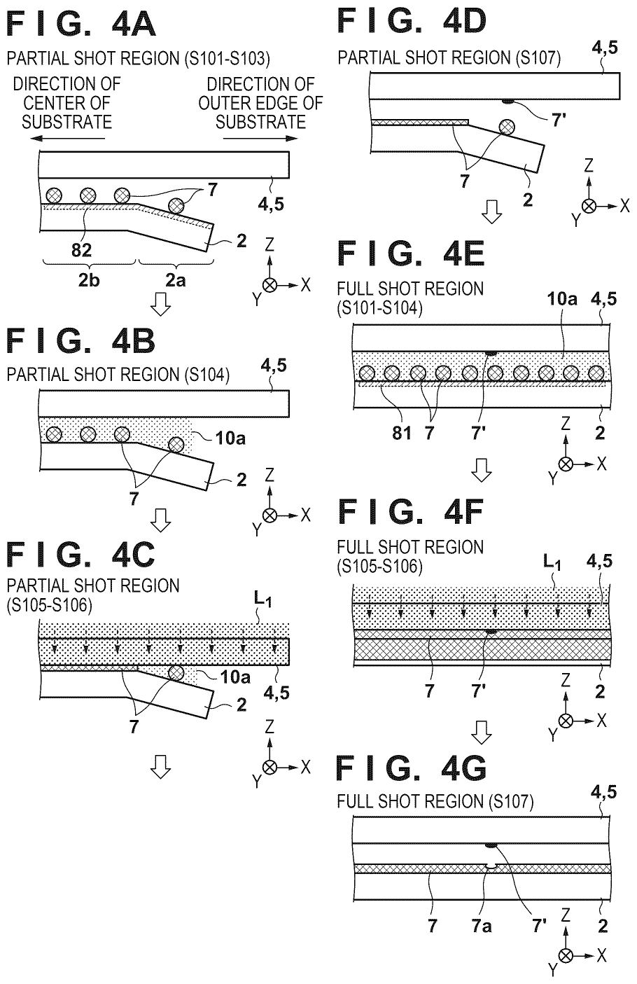

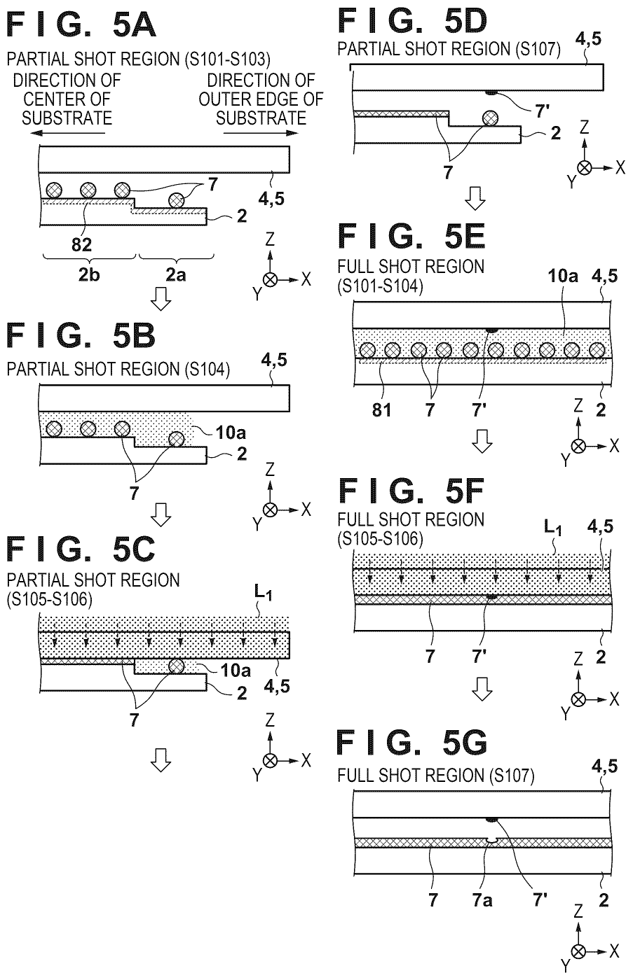

The conventional imprint process will be described first with reference to FIGS. 4A to 4G and FIGS. 5A to 5G. FIGS. 4A to 4G and FIGS. 5A to 5G are views for explaining the conventional imprint process. FIGS. 4A to 4G show an example in which warpage has occurred in the outer edge portion 2a of the substrate 2. FIGS. 5A to 5G shows an example in which a stepped portion is formed on the outer edge portion 2a of the substrate 2. FIGS. 4A to 4G and FIGS. 5A to 5G show corresponding step numbers in the flowchart of FIG. 3.

FIGS. 4A to 4D and FIGS. 5A to 5D show examples of the conventional imprint process for the partial shot region 82. As described above, the partial shot region 82 includes the outer edge portion 2a of the substrate 2 where warpage or stepped portion is generated and a portion 2b other than the outer edge portion 2a.

FIGS. 4A and 5A each show a state after alignment between the pattern portion 5 of the mold 4 and the partial shot region 82 of the substrate 2 through steps S101 to S103. The imprint material 7 has been supplied in the form of droplets onto the partial shot region 82. In addition, as described above, droplets of the imprint material 7 have also been supplied onto the outer edge portion 2a of the substrate 2 to prevent the mold 4 from coming into direct contact with the substrate 2.

FIGS. 4B and 5B each show a state in which a gas supplying operation is performed with respect to the partial shot region 82 in step S104. As described above, the gas supplying operation is the operation of supplying the gas 10a having a low oxygen concentration to between the mold 4 and the substrate 2 and is performed to prevent the occurrence of a pattern defect (unfilled defect) due to mixing of air as air bubbles in the imprint material 7. In the imprint process for the partial shot region 82, a gas supplying operation is performed to supply the gas 10a to between the mold 4 and the substrate 2, and the gas 10a is also present on the outer edge portion 2a of the partial shot region 82. That is, the droplets of the imprint material 7 supplied onto the outer edge portion 2a of the partial shot region 82 are covered with the atmosphere of the gas 10a.

FIGS. 4C and 5C each show a state in which the mold 4 is brought into contact with the imprint material 7 on the partial shot region 82 in step S105, and the partial shot region 82 (the imprint material 7) is irradiated with light in step S106. The droplets of the imprint material 7 supplied onto the portion 2b other than the outer edge portion 2a of the partial shot region 82 are spread and filled between the mold 4 and the substrate 2 by the mold 4 (the pattern portion 5). In contrast, the droplets of the imprint material 7 supplied onto the outer edge portion 2a are not sufficiently spread by the mold 4, and the upper portions of the droplets are in slight contact with the mold 4. In this state, the imprint material 7 is cured by being irradiated with light from the light irradiator 1. Conventionally, the light irradiator 1 irradiates the entire partial shot region 82 including the outer edge portion 2a with light. For example, the first light irradiator 1a can irradiate the entire partial shot region 82 with the light L₁. Accordingly, the droplets of the imprint material 7 supplied onto the outer edge portion 2a are also cured by light irradiation.

FIGS. 4D and 5D each show a state in which the mold 4 is separated from the imprint material 7 cured on the partial shot region 82 in step S107. In this case, since the droplets of the imprint material 7 on the outer edge portion 2a of the substrate 2 are not sufficiently spread on the substrate 2, the adhesion with the substrate 2 is insufficient. For this reason, some of the droplets of the imprint material 7 on the outer edge portion 2a adhere to the pattern portion 5 of the mold 4 and remain as the residual imprint material 7′ on the pattern portion 5. Conventionally, the residual imprint material 7′ has been cured by being irradiated with light (a cured state). For this reason, the next imprint process is performed while the cured residual imprint material 7′ remains on the pattern portion 5 of the mold 4.

FIGS. 4E to 4G and FIGS. 5E to 5G each show a conventional example of the next imprint process. The following exemplifies a case where the next imprint process is an imprint process for the full shot region 81. However, the same applies to a case where the next imprint process is an imprint process for another partial shot region 82.

FIGS. 4E and 5E each show a state after a gas supplying operation on the full shot region 81 through steps S101 to S104. FIGS. 4F and 5F each show a state in which the mold 4 is brought into contact with the imprint material 7 on the full shot region 81 in step S105, and the full shot region 81 (the imprint material 7) is irradiated with light in step S106. Steps S101 to S106 are performed while the cured residual imprint material 7′ adheres to the mold 4 (the pattern portion 5) in the imprint process for the partial shot region 82. Note that the first light irradiator 1a can irradiate the full shot region 81 with the light L₁.

FIGS. 4G and 5G each show a state in which the mold 4 is separated from the cured imprint material 7 on the full shot region 81 in step S107.

Conventionally, the cured residual imprint material 7′ adhering to the mold 4 (the pattern portion 5) comes into contact with the imprint material 7 spread on the full shot region 81 by the mold 4. The cured residual imprint material 7′ remains on the pattern portion 5 even after the mold 4 is separated from the imprint material 7 cured on the full shot region 81. As a result, a pattern defect (unfilled defect) can occur in a portion 7a with which the cured residual imprint material 7′ of the cured imprint material 7 on the full shot region 81 is in contact.

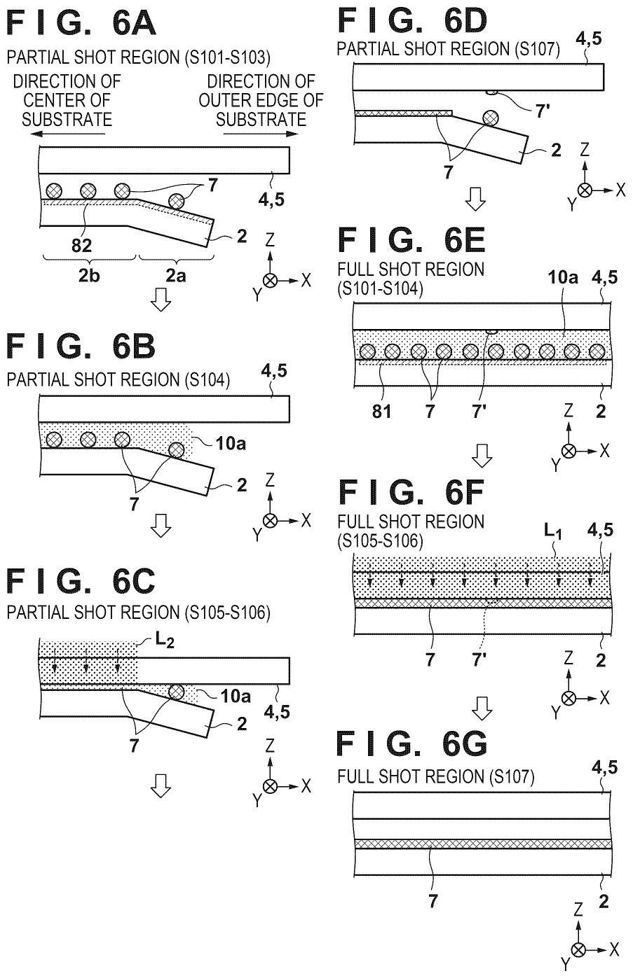

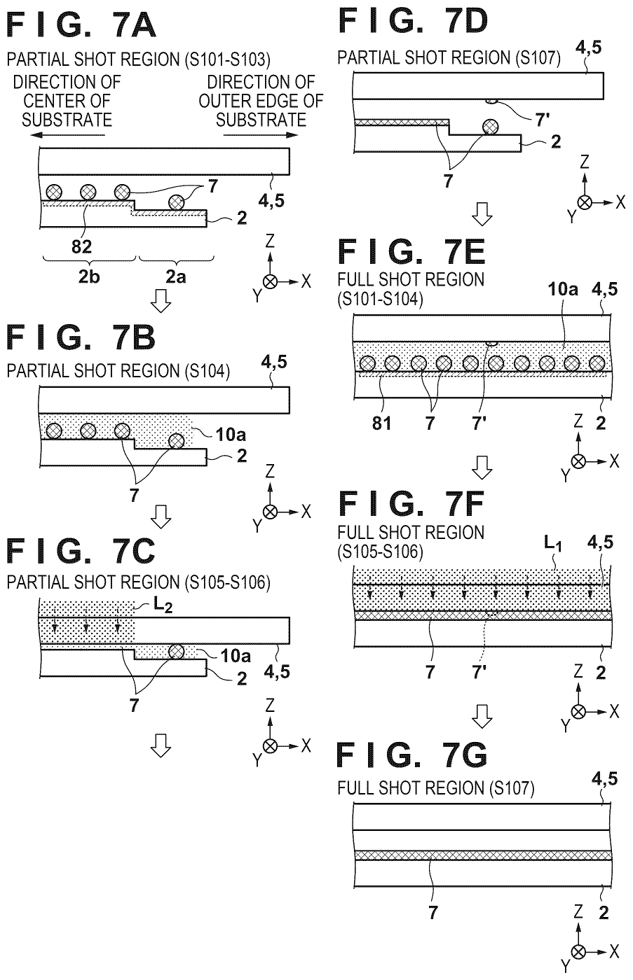

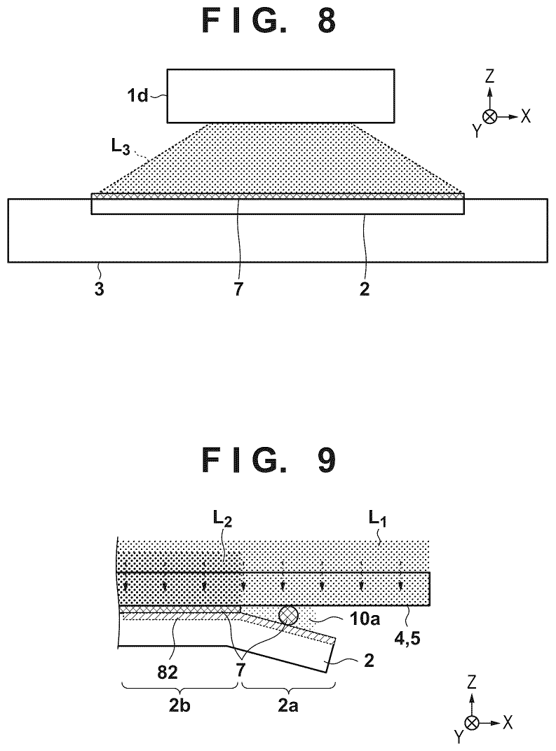

The imprint process according to the present embodiment will be described with reference to FIGS. 6A to 6G and FIGS. 7A to 7G. FIGS. 6A to 6G and FIGS. 7A to 7G are views for explaining the imprint process according to the present embodiment. FIGS. 6A to 6G show an example in which deflection has occurred in the outer edge portion 2a of the substrate 2. FIGS. 7A to 7G show an example in which a stepped portion is generated on the outer edge portion 2a of the substrate 2. FIGS. 6A to 6G and FIGS. 7A to 7G show corresponding step numbers in the flowchart of FIG. 3.

FIGS. 6A to 6D and FIGS. 7A to 7D show examples of the imprint process for the partial shot region 82 according to the present embodiment. As described above, the partial shot region 82 includes the outer edge portion 2a of the substrate 2 where deflection or a stepped portion is generated.

FIGS. 6A and 7A each show a state after alignment between the pattern portion 5 of the mold 4 and the partial shot region 82 of the substrate 2 through steps S101 to S103. The imprint material 7 has been supplied in the form of droplets onto the partial shot region 82. In addition, as described above, droplets of the imprint material 7 have also been supplied onto the outer edge portion 2a of the substrate 2 to prevent the mold 4 from coming into direct contact with the substrate 2.

FIGS. 6B and 7B each show a state in which a gas supplying operation is performed with respect to the partial shot region 82 in step S104. In the imprint process for the partial shot region 82, a gas supplying operation is performed to supply the gas 10a to between the mold 4 and the substrate 2, and the gas 10a is also present on the outer edge portion 2a of the partial shot region 82. That is, the droplets of the imprint material 7 supplied onto the outer edge portion 2a of the partial shot region 82 are covered with the atmosphere of the gas 10a.

In this case, as described above, the imprint material 7 contains at least a polymerizable compound and a photopolymerization initiator. The imprint material 7 is cured when the radicals generated from the photopolymerization initiator irradiated with light (ultraviolet light) cause a polymerization reaction of the polymerizable compound. Oxygen reacts with the radicals generated from the photopolymerization initiator irradiated with light (ultraviolet light) to eliminate the radicals. This inhibits the polymerization reaction of the polymerizable compound. This means that oxygen inhibits curing of the imprint material 7. Accordingly, in the imprint process for the partial shot region 82, a gas supplying operation may be controlled to reduce the amount of a gas 10b supplied to between the mold 4 and the substrate 2 as compared with the imprint process for the full shot region 81. This makes it possible to reduce the concentration of the gas 10b between the mold 4 and the substrate 2, that is, to increase the concentration of oxygen that inhibits curing of the imprint material 7, in the imprint process for the partial shot region 82 as compared with in the imprint process for the full shot region 81. For example, in the gas supplying operation in the imprint process for the partial shot region 82, the gas 10a need not be supplied to between the mold 4 and the substrate 2.

FIGS. 6C and 7C each show a state in which the mold 4 is brought into contact with the imprint material 7 on the partial shot region 82 in step S105, and the partial shot region 82 (the imprint material 7) is irradiated with light in step S106. In the present embodiment, the light irradiator 1 irradiates the outer edge portion 2a with an irradiation light amount per unit area which is smaller than that on the portion other than the outer edge portion 2a in a curing step (step S106) for the partial shot region 82. For example, the portion 2b other than the outer edge portion 2a is irradiated with the light L₂, and the outer edge portion 2a is not irradiated with the light L₂ by using the second light irradiator 1b configured to be able to change the irradiation region of light. This makes it possible to cure only the imprint material 7 on the portion 2b other than the outer edge portion 2a without curing the imprint material 7 on the outer edge portion 2a in a curing step for the partial shot region 82.

FIGS. 6D and 7D each show a state in which the mold 4 is separated from the imprint material 7 cured on the partial shot region 82 in step S107. In this case, some of the droplets of the imprint material 7 on the outer edge portion 2a adhere to the pattern portion 5 of the mold 4 and remain as the residual imprint material 7′ on the pattern portion 5. In the present embodiment, as described above, since the imprint material 7 on the outer edge portion 2a is kept in an uncured state, the residual imprint material 7′ adhering to the mold 4 (the pattern portion 5) also remains in the uncured state. That is, the next imprint process is performed while the residual imprint material 7′ adhering to the mold 4 remains in the uncured state. The residual imprint material 7′ in the uncured state which is adhering to the mold 4 is vaporized and eliminated with the lapse of time if the amount of the residual imprint material 7′ is small. Accordingly, there is little possibility that a pattern defect will be formed in the next imprint process. Even if the next imprint process is performed before the residual imprint material 7′ is eliminated, the uncured residual imprint material 7′ adhering to the mold 4 is integrated (mixed, merged, or fused) with the imprint material 7 supplied onto the substrate 2 in the next imprint process. This makes it possible to perform the next imprint process without waiting for the elimination of the uncured residual imprint material 7′.

FIGS. 6E to 6G and FIGS. 7E to 7G each show an example of the next imprint process in the present embodiment. The following exemplifies a case where the next imprint process is an imprint process for the full shot region 81. However, the same applies to a case where the next imprint process is an imprint process for another partial shot region 82.

FIGS. 6E and 7E each show a state after a gas supplying operation on the full shot region 81 through steps S101 to S104. FIGS. 6F and 7F each show a state in which the mold 4 is brought into contact with the imprint material 7 on the full shot region 81 in step S105, and the full shot region 81 (the imprint material 7) is irradiated with light in step S106. The first light irradiator 1a can irradiate the full shot region 81 with the light L₁. FIGS. 6G and 7G each show a state in which the mold 4 is separated from the cured imprint material 7 on the full shot region 81 in step S107. In the present embodiment, the residual imprint material 7′ adhering to the pattern portion 5 of the mold 4 is in the uncured state. Accordingly, when the mold 4 (the pattern portion 5) comes into contact with the imprint material 7 on the full shot region 81, the residual imprint material 7′ is integrated with the imprint material 7 on the full shot region 81. This can reduce the occurrence of pattern defects (unfiled defects) caused by the residual imprint material 7′ in the cured imprint material 7 on the full shot region 81.

In this case, the imprint process according to the present embodiment uses the first light irradiator 1a in a curing step for the full shot region 81. However, limitation is not made thereto, and the second light irradiator 1b may be used. Note, however, that since the second light irradiator 1b includes the optical adjuster 1b₂ (spatial light modulator), and the components and the design mechanism are more complex than the first light irradiator 1a, the durability of the second light irradiator 1b may be lower than that of the first light irradiator 1a. Therefore, in order to suppress a deterioration in the second light irradiator 1b, it is desirable that the first light irradiator 1a is used in the imprint process for the full shot region 81.

In the present embodiment, the gas supplying operation (step S104) is performed before the contact step (step S105). However, limitation is not made thereto, and the gas supplying operation may not be performed. In this case, since oxygen is present around the imprint material 7 supplied onto the outer edge portion 2a, the oxygen can inhibit curing of the imprint material 7 even with irradiation with light. Note, however, that even if curing is inhibited, the property of the imprint material 7 sometimes changes (for example, the viscosity increases) upon light irradiation. If the residual imprint material 7′ adhering to the mold 4 changes in property upon light irradiation, the residual imprint material 7′ is not integrated with the imprint material 7 on the shot region 8 for which the imprint process is performed next and hence can be a factor that causes a pattern defect. Accordingly, even if a gas supplying operation is not performed, light irradiation in a curing step for the partial shot region 82 may be controlled such that the irradiation light amount per unit area for the outer edge portion 2a is smaller than that for the portion 2b other than the outer edge portion 2a. For example, light irradiation in a curing step for the partial shot region 82 can be controlled so as not to irradiate the outer edge portion 2a with light.

### [Additional Light Irradiation]

If the imprint process is performed for the partial shot region 82 as described above, there can be, for example, a problem (event) that the droplets of the imprint material 7 on the outer edge portion 2a are kept in the uncured state and flow to adhere to other members and components. In addition, the second light irradiator 1b used to cure the imprint material 7 on the partial shot region 82 is sometimes controlled to limit the output of the light source 1b₁ to an output smaller than the output of the light source lai of the first light irradiator 1a in order to keep the durability and controllability of the optical adjuster 1b₂ (spatial light modulator). In this case, the intensity of the light L₂ emitted from the second light irradiator 1b can be smaller than the intensity of the light L₁ emitted from the first light irradiator 1a. This can also cause, for example, a problem (event) that the imprint material 7 on the partial shot region 82 is not cured to a target hardness, and the pattern of the imprint material 7 formed on the partial shot region 82 through a mold-separating step is collapsed or distorted due to the lapse of time or disturbance.

In the imprint apparatus 100 according to the present embodiment, after a mold-separating step (step S107) for the partial shot region 82, the partial shot region 82 (overall) is additionally irradiated with light to increase the hardness of the imprint material 7 on the partial shot region 82. Additional irradiation of light on the partial shot region 82 will sometimes be written as “additional light irradiation” hereinafter. Such additional light irradiation can cure the droplets of the imprint material 7 on the outer edge portion 2a of the partial shot region 82 and cure the imprint material 7 on the partial shot region 82 to a target hardness.

FIG. 8 shows an example of performing additional light irradiation by using a third light irradiator 1d. The third light irradiator 1d is configured to irradiate the entire substrate 2 with light. Additional light irradiation for the partial shot region 82 is performed by collectively irradiating the entire region of the substrate 2 (that is, the plurality of shot regions 8) with light by using the third light irradiator 1d. The third light irradiator 1d is provided as a constituent element of the light irradiator 1 in the imprint apparatus 100. Moving the substrate stage 3 after the imprint process can place the substrate 2 below the third light irradiator 1d. Light L₃ emitted from the third light irradiator 1d is light that causes a photopolymerization reaction of the imprint material 7. The light L₃ is, for example, ultraviolet light. As the light source of the third light irradiator 1d, for example, a lamp, laser diode, or light emitting diode (LED) can be used.

In this case, in the present embodiment, the third light irradiator 1d is a constituent element of the imprint apparatus 100. However, limitation is not made thereto, and the third light irradiator 1d may be formed as an external device of the imprint apparatus 100. In addition, in the present embodiment, the substrate 2 is placed below the third light irradiator 1d by moving the substrate stage 3. However, limitation is not made thereto, and a second substrate stage different from the substrate stage 3 may be provided below the third light irradiator 1d. In this case, it is possible to convey the substrate 2 having undergone the imprint process from on the substrate stage 3 onto the substrate 2 by using a convey mechanism (not shown). The second substrate stage may be configured to be moved by the convey mechanism to a substrate receiving position for receiving the substrate 2.

An example of the imprint process and additional light irradiation for a plurality of shot regions 8 on the substrate 2 will be described. For example, first of all, the imprint process is performed for each of the plurality of full shot regions 81 arranged in the central area of the substrate 2 by using the first light irradiator 1a. When the imprint process for all the full shot regions 81 is completed, the imprint process is performed for each of the plurality of partial shot regions 82 arranged in the peripheral area of the substrate 2 by using the second light irradiator 1b. When the imprint process for all the partial shot regions 82 is completed, the substrate 2 is placed (conveyed) below the third light irradiator 1d, and additional light irradiation is collectively performed for the plurality of shot regions 8 (for example, the entire region of the substrate 2) having undergone the imprint process by using the third light irradiator 1d. This makes it possible to cure the droplets of the imprint material 7 on the outer edge portions 2a of the partial shot regions 82 and also cure the imprint material 7 on the partial shot regions 82 to a target hardness.

As described above, the imprint apparatus 100 according to the present embodiment causes the light irradiator 1 to perform light irradiation in the imprint process (a curing step) for the partial shot region 82 so as to make the irradiation light amount per unit area on the outer edge portion 2a become smaller than that on a portion other than the outer edge portion 2a. This makes it possible to keep the residual imprint material 7′ adhering to the pattern portion 5 of the mold 4 in the imprint process for the partial shot region 82 in the uncured state. As a result, it is possible to reduce the occurrence of pattern defects due to the residual imprint material 7′ in succeeding the imprint process. That is, it is possible to reduce defects occurring in the imprint material 7 on the substrate 2 in the imprint process. In addition, the imprint apparatus 100 according to the present embodiment performs additional light irradiation for the partial shot region 82 in a mold-separating step for the partial shot region 82. This makes it possible to cure the droplets of the imprint material 7 on the outer edge portion 2a of the partial shot region 82 and also cure the imprint material 7 on the partial shot region 82 to a target hardness.

### Second Embodiment

The second embodiment of the present invention will be described. The first embodiment has exemplified the case where the light irradiator 1 performs light irradiation so as not to irradiate the outer edge portion 2a with light in the imprint process (a curing step) for the partial shot region 82. The second embodiment will exemplify a case where in the imprint process (a curing step) for a partial shot region 82, a light irradiator 1 also irradiates an outer edge portion 2a with light so as to make the irradiation light amount per unit area for the outer edge portion 2a become smaller than that for the portion other than the outer edge portion 2a. Note that the present embodiment basically inherits the first embodiment and can comply with the first embodiment except for the matters described below.

As described above, the second light irradiator 1b is sometimes controlled to limit the output of the light source 1b₁ to an output smaller than the output of the light source lai of the first light irradiator 1a in order to keep the durability and controllability of the optical adjuster 1b₂ (spatial light modulator). In this case, the hardness of the imprint material 7 on the partial shot region 82 which is cured by using the second light irradiator 1b may be smaller than the hardness of the imprint material 7 on the full shot region 81 which is cured by using the first light irradiator 1a. If the hardness of the cured imprint material 7 is insufficient, the pattern of the cured imprint material 7 formed through a mold-separating step may be collapsed or distorted. In addition, even after a mold-separating step, the pattern of the cured imprint material 7 may be collapsed or distorted due to thermal deformation or vibration.

Accordingly, in the present embodiment, as shown in FIG. 9, in the imprint process (a curing step) for the partial shot region 82, the partial shot region 82 is irradiated with light L₁ from a first light irradiator 1a and light L₂ from a second light irradiator 1b. More specifically, the first light irradiator 1a irradiates the entire partial shot region 82 with the light L₁, and the second light irradiator 1b irradiates only a portion 2b of the partial shot region 82 other than the outer edge portion 2a with the light L₂. With this operation, the outer edge portion 2a of the partial shot region 82 is irradiated with only the light L₁, and the portion 2b other than the outer edge portion 2a is irradiated with both the light L₁ and the light L₂.

In using the first light irradiator 1a in the imprint process (a curing step) for the partial shot region 82, the irradiation light amount of the light L₁ from the first light irradiator 1a is adjusted so as not to cure the imprint material 7 on the outer edge portion 2a of the partial shot region 82. The irradiation light amount of the light L₁ from the first light irradiator 1a may be adjusted by controlling the illuminance (light intensity) or irradiation time of the light L₁ or controlling both the illuminance and irradiation time of the light L₁. In addition, the first light irradiator 1a and the second light irradiator 1b may be controlled to irradiate the partial shot region 82 with the light L₁ and the light L₂ simultaneously (at the same timing).

Irradiating the outer edge portion 2a of the partial shot region 82 with only the light L₁ from the first light irradiator 1a in this manner can reduce the fluidity of the imprint material 7 on the outer edge portion 2a without curing the imprint material 7. In addition, the portion of the partial shot region 82 other than the outer edge portion 2a is irradiated with the light L₂ from the second light irradiator 1b in addition to the light L₁ from the first light irradiator 1a. This makes it possible to cure the imprint material 7 on the portion 2b other than the outer edge portion 2a. This can reduce the occasion where the pattern of the cured imprint material 7 is collapsed or distorted in or after a mold-separating step.

In this case, since the entire surface of a pattern portion 5 of a mold 4 is irradiated with the light L₁ from the first light irradiator 1a, the imprint material 7 on the outer edge portion 2a is also irradiated with the light. However, the irradiation light amount is adjusted so as not to cure the imprint material 7. Accordingly, the imprint material 7 on the outer edge portion 2a is not cured by irradiation with the light L₁. Consequently, a residual imprint material 7′ adhering to the mold 4 (the pattern portion 5) is also uncured. Therefore, the residual imprint material 7′ adhering to the mold 4 is integrated with the imprint material 7 supplied onto the substrate 2 in the next imprint process. This can reduce the occurrence of pattern defects (unfilled defects) caused by the residual imprint material 7′.

### Third Embodiment

The third embodiment of the present invention will be described. The first embodiment has exemplified the case where additional light irradiation for the partial shot region 82 is performed by collectively irradiating the plurality of shot regions 8 with the light L₃ by using the third light irradiator 1d. The third embodiment will exemplify a case where additional light irradiation for a partial shot region 82 is performed by using a first light irradiator 1a in the imprint process (a curing step) for another shot region 8. Note that the present embodiment basically inherits the first embodiment and can comply with the first embodiment except for the matters described below. In addition, the second embodiment may be applied to the present embodiment.

In the present embodiment, the first light irradiator 1a includes a mechanism for changing the irradiation region of light L₁ and is configured to be able to spread the irradiation region of the light L₁ to the outside of a pattern portion 5 of a mold 4. In imprint processing (a curing step) for the shot region 8 different from the partial shot region 82 having undergone the imprint process, the first light irradiator 1a collectively irradiates a range including the partial shot region 82 and the different shot region 8 with the light L₁. This makes it possible to perform additional light irradiation for the partial shot region 82. In this case, the different shot region 8 (second region) may be adjacent to the partial shot region 82 or a full shot region 81.

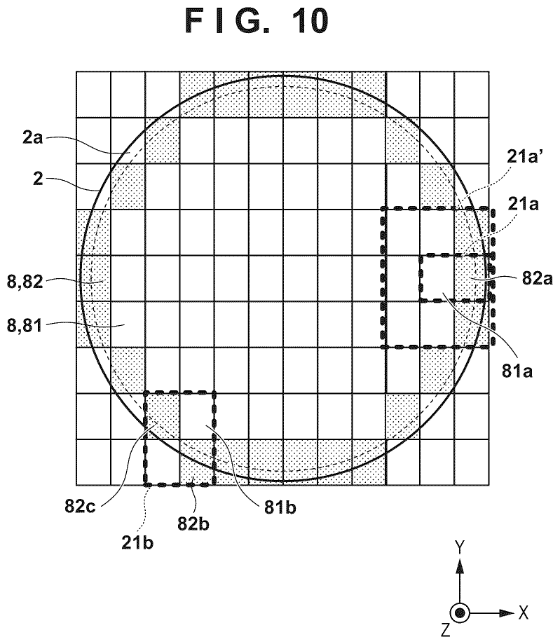

FIG. 10 is a view for explaining additional light irradiation for the partial shot region 82 in the present embodiment, showing a placement example of the plurality of shot regions 8 on the substrate 2. Assume a case where the imprint process is performed for a full shot region 81a after the imprint process for a partial shot region 82a. In this case, in a curing step for the full shot region 81a, the irradiation region of the light L₁ by the first light irradiator 1a is expanded to a range 21a indicated by the broken line so as to include the full shot region 81a and the partial shot region 82a. The first light irradiator 1a collectively irradiates the range 21a including the full shot region 81a and the partial shot region 82a with the light L₁. In light irradiation in the imprint process (a curing step) for the full shot region 81a, additional light irradiation for the partial shot region 82a can also be performed. This is advantageous in terms of throughput.

In this case, if the imprint process for the shot regions 8 (including the partial shot region 82a) around the full shot region 81a is completed, the irradiation region of the light L₁ by the first light irradiator 1a may be expanded to a range 21a′ so as to include the surrounding shot regions 8. Note, however, that in expanding the irradiation region of the light L₁ by the first light irradiator 1a to the range 21a′, the irradiation area of the light L₁ for a substrate 2 is large as compared with the case of expanding to the range 21a, and the amount of heat input to the substrate 2 increases accordingly. As the amount of heat input to the substrate 2 increases, unnecessary thermal deformation can occur in the shot region 8, resulting in a deterioration in the overlay accuracy between the mold 4 and the pattern portion 5. Accordingly, if high overlay accuracy is required, it is desired that the irradiation region of the light L₁ by the first light irradiator 1a should be the range 21a including only the full shot region 81a and the partial shot region 82a.

Assume that the imprint process is performed for a full shot region 81b after the imprint process is continuously performed for partial shot regions 82b and 82c. In this case, in a curing step for the full shot region 81b, the irradiation region of the light L₁ by the first light irradiator 1a is expanded to the range 21b so as to include the full shot region 81b and the partial shot regions 82b and 82c. The first light irradiator 1a collectively irradiates the range 21b including the full shot region 81b and the partial shot regions 82b and 82c with the light L₁. This makes it possible to perform additional light irradiation for the plurality of partial shot regions 82b and 82c in light irradiation in the imprint process (a curing step) for the full shot region 81b, thus providing advantage in terms of throughput.

The present embodiment has exemplified the case where in the imprint process (a curing step) for the full shot region 81, additional light irradiation is performed for the partial shot region 82 by collectively irradiating the range including the full shot region 81 and the partial shot region 82 with light. However, limitation is not made thereto, and the range including the full shot region 81 and the partial shot region 82 may be collectively irradiated with light after the end of the imprint process for each of the full shot region 81 and the partial shot region 82. For example, after the end of the imprint process for each of the full shot region 81a and the partial shot region 82a, the range 21a including the full shot region 81a and the partial shot region 82a is collectively irradiated with light. This also makes it possible to perform additional light irradiation for the partial shot region 82.

### <Embodiment of Article Manufacturing Method>

An article manufacturing method according to an embodiment of the present invention is suitable for manufacturing an article, for example, a microdevice such as a semiconductor device or an element having a fine structure.

The article manufacturing method according to this embodiment includes a shaping step of shaping a composition on a substrate using the above-described shaping method by a shaping apparatus, a processing step of processing the substrate that has the composition shaped by the shaping step, and a manufacturing step of manufacturing an article from the substrate processed by the processing step. As the shaping apparatus, an imprint apparatus or a planarization apparatus can be used. The manufacturing method also includes other known steps (oxidation, deposition, vapor deposition, doping, planarization, etching, resist removal, dicing, bonding, packaging, and the like). The article manufacturing method according to this embodiment is advantageous in at least one of the performance, quality, productivity, and production cost of the article, as compared to conventional methods.

The pattern of a cured product shaped using the shaping apparatus described above is used permanently for at least some of various kinds of articles or temporarily when manufacturing various kinds of articles. The articles are an electric circuit element, an optical element, a MEMS, a recording element, a sensor, a mold, or the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. The mold includes an imprint mold or the like.

The pattern of the cured product is directly used as the constituent member of at least some of the above-described articles or used temporarily as a resist mask. After etching or ion implantation is performed in the substrate processing step, the resist mask is removed.

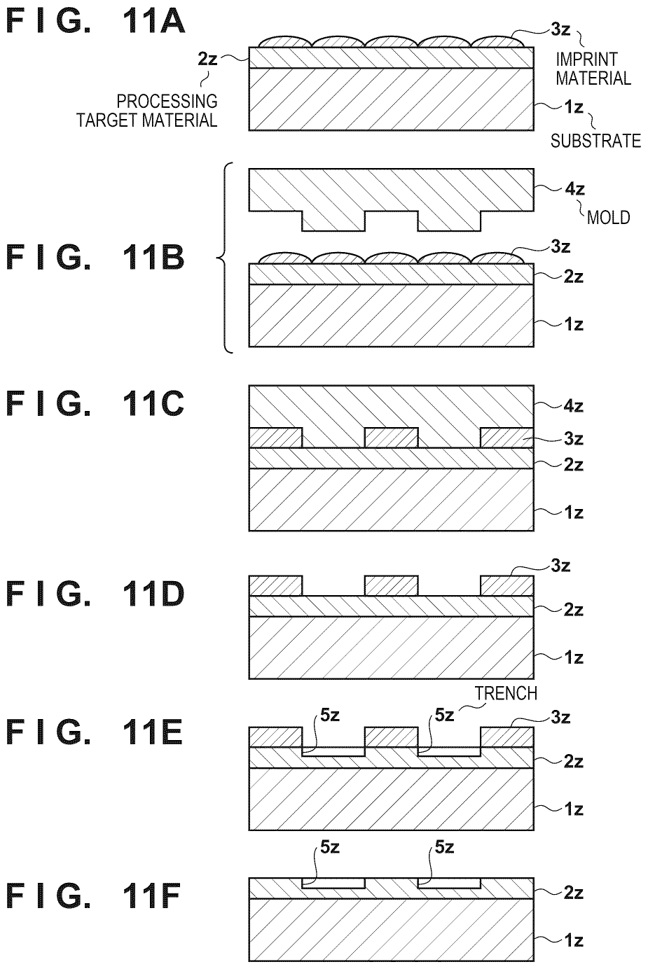

A practical article manufacturing method in a case where an imprint apparatus is used as a shaping apparatus will be described next. As shown FIG. 11A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 11B, a side of a mold 4z for imprint with a convex-concave pattern is directed to face the imprint material 3z on the substrate. As shown FIG. 11C, the mold 4z and the substrate 1z to which the imprint material 3z has been applied are brought into contact with each other, and a pressure is applied. The gap between the mold 4z and the processed material 2z is filled with the imprint material 3z. In this state, when the imprint material 3z is irradiated with light as curing energy via the mold 4z, the imprint material 3z is cured.

As shown in FIG. 11D, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the convex-concave pattern of the mold 4z is transferred to the imprint material 3z.

As shown in FIG. 11E, when etching is performed using the pattern of the cured product as an etching resistant mask, a portion of the surface of the processed material 2z where the cured product does not exist or remains thin is removed to form a groove 5z. As shown in FIG. 11F, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-076691 filed on May 9, 2024, which is hereby incorporated by reference herein in its entirety.

What is claimed is:

1. A shaping method of performing a process of shaping a composition on a substrate by using a mold, with respect to each of a plurality of regions on the substrate, wherein
the process includes curing the composition on the substrate by light irradiation in a state where the mold and the composition are in contact with each other and separating the mold from the cured composition,
the plurality of regions including a first region having an outer edge portion of the substrate, and
the light irradiation is performed so as to make an irradiation light amount per unit area for the outer edge portion become smaller than that for a portion other than the outer edge portion, in the curing for the first region, and the first region is additionally irradiated with light after the separating for the first region.

2. The method according to claim 1, wherein the outer edge portion has a surface lower in height than a portion other than the outer edge portion.

3. The method according to claim 1, wherein the first region is additionally irradiated with light by collectively irradiating the plurality of regions with light after an end of the process for each of the plurality of regions.

4. The method according to claim 1, wherein the plurality of regions include a second region different from the first region, and
the first region is additionally irradiated with light by collectively performing the light irradiation for a range including the first region and the second region in the curing for the second region.

5. The method according to claim 4, wherein the second region is a region of the plurality of regions which is adjacent to the first region.

6. The method according to claim 4, wherein the second region is a region of the plurality of regions which does not include the outer edge portion.

7. The method according to claim 1, wherein the plurality of regions include a second region different from the first region, and
the first region is additionally irradiated with light by collectively irradiating a range including the first region and the second region with light after an end of the process for each of the first region and the second region.

8. The method according to claim 7, wherein the second region is a region of the plurality of regions which is adjacent to the first region.

9. The method according to claim 7, wherein the second region is a region of the plurality of regions which does not include the outer edge portion.

10. The method according to claim 1, wherein the entire first region is additionally irradiated with light after the separating for the first region.

11. The method according to claim 1, wherein the first region is additionally irradiated with light so as to increase hardness of the composition on the first region after the separating for the first region.

12. The method according to claim 1, wherein the composition on the substrate has a property of being inhibited by oxygen from being cured, and
the process further includes supplying a gas having a lower oxygen concentration than air to between the mold and the substrate before the mold is brought into contact with the composition on the substrate.

13. An article manufacturing method comprising:
shaping a composition on a substrate by using a shaping method defined in claim 1;
processing the substrate having the composition shaped in the shaping; and
manufacturing an article from the substrate processed in the processing.

14. A shaping apparatus that performs, for each of a plurality of regions on a substrate, a process of shaping a composition on the substrate by curing the composition by light irradiation in a case where a mold and the composition are in contact with each other and separating the mold from the cured composition, the apparatus comprising:
a light irradiator configured to irradiate the substrate with light; and
a controller configured to control the process,
wherein the plurality of regions include a first region having an outer edge portion of the substrate, and
wherein the controller is configured to control the light irradiation using the light irradiator so as to make an irradiation light amount per unit area for the outer edge portion become smaller than that for a portion other than the outer edge portion, in the process for the first region, and additionally irradiate the first region with light by the light irradiator after separating the mold from the cured composition.
